(19) United States
(12) Patent Application Publication
(10) Pub. No.: US 2018/0014400 A1
(43) Pub. Date: Jan. 11, 2018

(54) COMPUTING DEVICE BONDING ASSEMBLIES

(71) Applicant: Microsoft Technology Licensing, LLC, Redmond, WA (US)

(72) Inventors: Rajesh DIGHDE, Redmond, WA (US); Andrew N. CADY, Kirkland, WA (US); Camilo LEON, Redmond, WA (US); Kabir SIDDIQUI, Sammamish, WA (US)

(73) Assignee: Microsoft Technology Licensing, LLC, Redmond, WA (US)

(21) Appl. No.: 15/714,813

(22) Filed: Sep. 25, 2017

Related U.S. Application Data
(63) Continuation of application No. 14/714,074, filed on May 15, 2015.

(51) Int. Cl. H05K 1/02; H05K 5/00; H05K 1/18; H04M 1/02; G06F 1/16; H04N 5/64

(52) U.S. Cl. CPC H05K 1/028; H04M 1/0266; G06F 1/1605; G06F 1/1626; H05K 5/0017; H05K 1/181; G06F 1/1601; G06F 1/1637; G06F 1/163; H04M 1/0268; H04N 5/64; H05K 2201/10136

(57) ABSTRACT

The description relates to display devices. One example can include an integrative display chassis defining a major planar surface and having a feature formed relative to the major planar surface. The example can also include a display positioned relative to the integrative display chassis and extending along the major planar surface defined by the integrative display chassis. The example can further include an electronic component positioned in the feature and oriented relative to the major planar surface by the feature.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the FIG. and associated discussion where the reference number is first introduced.

FIG. 1 is a perspective view of an example display device implementation in accordance with the present concepts.

FIGS. 2-8 are sectional views of example display device implementations in accordance with the present concepts.

### DESCRIPTION

The present concepts relate to display devices and components of display devices. Traditionally, a set of display components are secured together in a display chassis of a display device. The display chassis is then positioned in a system chassis of the display device. The system chassis can also be associated with other components, such as various sensors like cameras (e.g., visible light cameras and/or depth cameras). The sensors can then be oriented relative to the display. The present concepts can replace the display chassis and the system chassis with a single integrative display chassis. The single integrative display chassis can provide a larger effective display area (e.g. active area) for given display device dimensions. Further, the integrative display chassis can provide inherent orientation of the cameras and the display. Thus, the present implementations can provide superior display devices compared to traditional techniques and can produce these superior display devices with fewer components than traditional techniques.

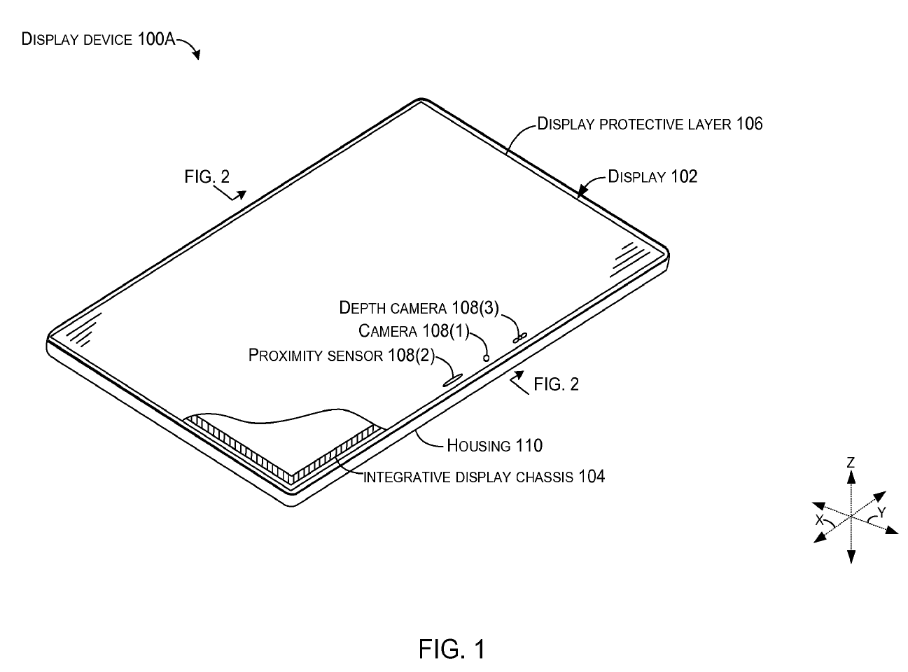

FIG. 1 shows a partial cut-away view of an example display device 100A manifest as a tablet type computing device. The display device 100A can include a display 102 positioned relative to an integrative display chassis 104. In this case, a top most (e.g. exposed) layer of the display is manifest as a display protective layer 106. Additional electronic components, such as camera 108(1), proximity sensor 108(2), and/or depth camera 108(3) can be positioned in the integrative display chassis 104. The integrative display chassis can define a major planar surface (e.g. the xy reference plane) upon which the display protective layer 106 is positioned. Further, the integrative display chassis can orient the camera 108(1) orthogonally (e.g., along the z reference axis) to the major planar surface. In this case, a decorative housing 110 is positioned around the integrative display chassis 104. In other configurations, the integrative display chassis may also perform this role and thereby the decorative housing 110 can be eliminated.

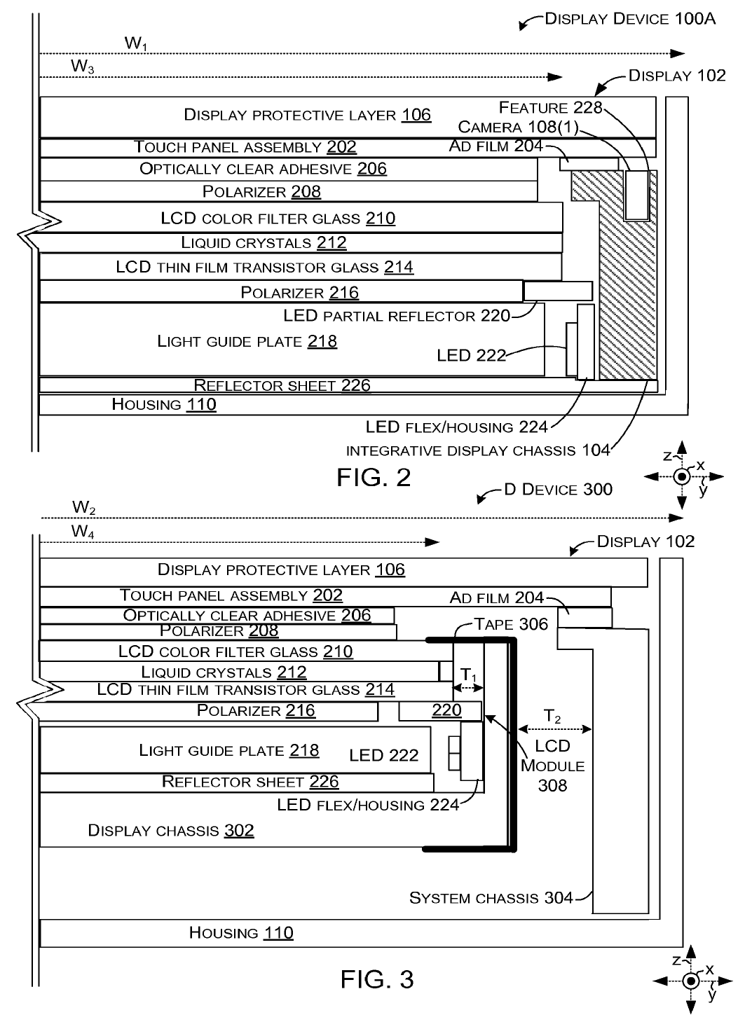

FIG. 2 shows a sectional view of display device 100A as indicated in FIG. 1. (Note that due to space constraints only a portion of the sectional view is represented on the drawing page). In this case, illustrated components of the display device 100A include the display protective layer 106, touch panel assembly 202, adhesive film 204, optically clear adhesive 206, polarizer 208, LCD color filter glass 210, liquid crystals 212, LCD thin film transistor (TFT) glass 214, polarizer 216, light guide plate 218, LED partial reflector 220, LED 222, LED flex/housing 224, reflector sheet 226, housing 110, feature 228, camera 108(1), and/or integrative display chassis 104.

Components 210-226 (e.g., LCD color filter glass 210, liquid crystals 212, LCD thin film transistor glass 214, polarizer 216, light guide plate 218, LED partial reflector 220, LED 222, LED flex/housing 224, and reflector sheet 226) can be positioned within and/or supported by the integrative display chassis 104. Additional components (e.g., display protective layer 106, touch panel assembly 202, adhesive film 204, optically clear adhesive 206, polarizer 208) can be precisely embedded and/or aligned/oriented to the integrative display chassis 104 and hence to the surface of the display 102 such that components 210-226 are oriented in light transmitting relation to one another and to the additional components.

The integrative display chassis 104 can provide structural support to the interactive surface of display 102. The integrative display chassis 104 can provide easy assembly of the display device 100A. Further, the integrative display chassis can facilitate reworking and/or removal of display 102 from the display device 100A. Stated another way, the display protective layer 106, touch panel assembly 202, adhesive film 204, optically clear adhesive 206, and/or polarizer 208 can be removed from the display device, then the integrative display chassis 104 with components 210-226 can be removed. Components can be repaired or a new integrative display chassis with associated components 210-226 can be installed. The integrative display chassis 104 can be formed of any material that can provide structural support to the display components and/or allow features to be formed therein. Example materials can include various plastics, polymers, and/or composites, among others.

The display device 100A of FIG. 2 can be contrasted with FIG. 3 which shows a similar view of a traditionally configured display device 300. Display device 300 includes a display chassis 302 and a system chassis 304. In display device 300, the LCD color filter glass 210, liquid crystals 212, LCD thin film transistor (TFT) glass 214, polarizer 216, light guide plate 218, LED partial reflector 220, LED 222, LED flex/housing 224, and reflector sheet 226 are positioned within display chassis 302.

Construction of traditional display device 300 involves a cumulative stack build of reflector sheet 226, light guide plate 218, polarizer 216, LCD TFT glass 214, liquid crystals 212, and LCD color filter glass 210. These components are then enclosed by a metal display chassis 302. The metal display chassis tends to be heavy, thick, and/or can cause electrical interference with antennae performance. A tape 306 is required to hold the components relative to the display chassis 302 to form an LCD module 308. The tape 306 can impart mechanical stress forces on the LCD module 308 which can induce physical deformation on the LCD module 308 (e.g., the stress forces can cause the LCD module to be non-planar or warped which poses difficulty in subsequent display construction steps) and/or cause the display device 300 to be more prone to display artifacts.

Tolerances T₁ are employed between the components of the LCD module 308 and the display chassis 302 in the x and y reference directions. Additional tolerances T₂ are employed between the display chassis 302 and the system chassis 304 in the x and y reference directions. In contrast, the implementation of display device 100A shown in FIG. 2 eliminates at least tolerances T₂. This aspect is important because an effective display width (e.g. active area) of the display device is limited by the width of liquid crystals 212. Thus, given equivalent overall display device widths w₁ of display device 100A and w₂ of traditional display device 300, display device 100A offers a greater effective display width w₃ (e.g., active area) than the display width w₄ (e.g., active area) of traditional display device 300.

Furthermore, in relation to traditional display device 300, using an ultrathin glass (0.05 to 0.3 mm) or a hard plastic film for display protective layer 106, an overhang area beyond the active area (e.g., the delta between w₂ and w₄) needs to be supported during integration of LCD module 308 and display chassis 302 in system chassis 304 and housing 110.

Returning again to FIG. 2, the integrative display chassis 104 of display device 100A can provide features 228 into which electronic components can be positioned. For instance, in the illustrated configuration feature 228 is formed into the integrative display chassis 104. The feature can be formed in the integrative display chassis during formation of the integrative display chassis, such as during part of a 3D printing process, or the feature can be formed in an otherwise completed integrative display chassis (e.g., material removed from the integrative display chassis to form the feature).

The camera 108(1) can be positioned in this feature 228. Further, because the integrative display chassis 104 orients both the display 102 and the feature 228, the camera 108(1) can be automatically oriented by the integrative display chassis relative to the display. For instance, the integrative display chassis 104 defines the major planar surface (e.g., xy plane) and orients the camera orthogonally to the major planar surface via the orientation of feature 228. Stated another way, the integrative display chassis may have features that align the camera (or other component), for example, such that the center of the camera is in the center of a circular opening in the touch panel black border (x, y alignment), the rear of the camera housing is aligned to a precise z location (to prevent interference with another component), and the polar or azimuthal angle of the camera is set as well.

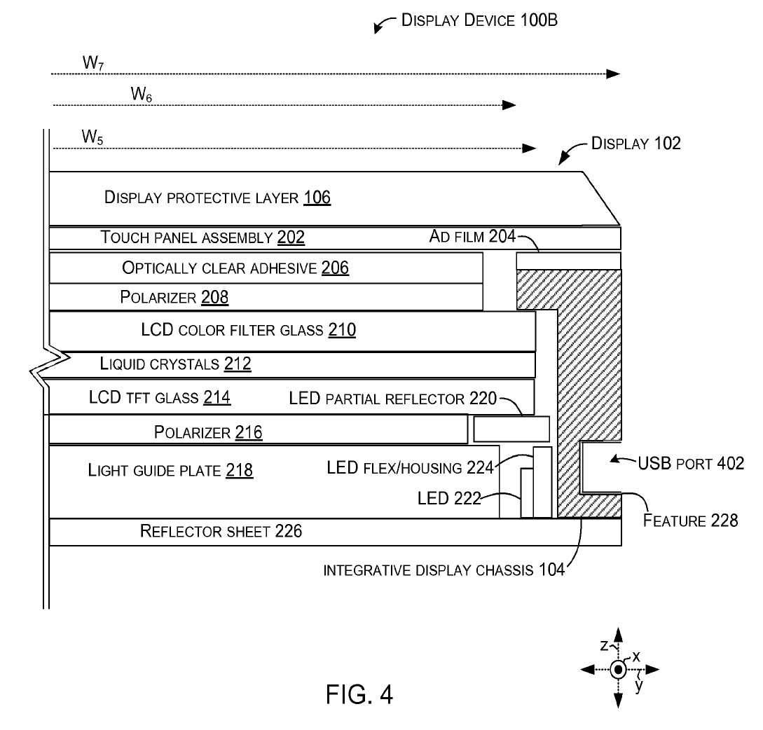

FIG. 4 shows another example display device 100B. In this configuration the LCD color filter glass 210, liquid crystals 212, and/or LCD color TFT glass 214 can be wider (e.g., width w₅) than a minimum width w₆ of the integrative display chassis 104. In one case, these components can be assembled from the bottom up (e.g., inserted from the bottom and layered sequentially top to bottom) starting with the LCD color filter glass 210, liquid crystals 212, LCD color TFT glass 214, etc. In this case, the integrative display chassis 104 can define feature 228 in which a USB port 402 is formed. Further, in this implementation, the integrative display chassis 104 can define an overall width w₇ of the display device (e.g., no housing is positioned around the integrative display chassis 104 and instead the integrative display housing provides the aesthetic outer surface visible to the user). This configuration can further contribute to increasing a size of the display device's active area relative to the display device's overall dimensions. Further, the integrative display chassis 104 can allow the display device's display protective layer 106 and touch panel assembly 202 to extend over the integrative display chassis 104 to the overall width w₇ while still adequately supporting the display protective layer.

Further, some implementations can achieve a robust snap fit of the display 102 and display protective layer 106 or touch panel assembly 202 onto the display device 102 without the use of adhesives. Such a configuration can be thought of as a reworkable display device 100A that offers easy removal of display 102 from a remainder of the display device.

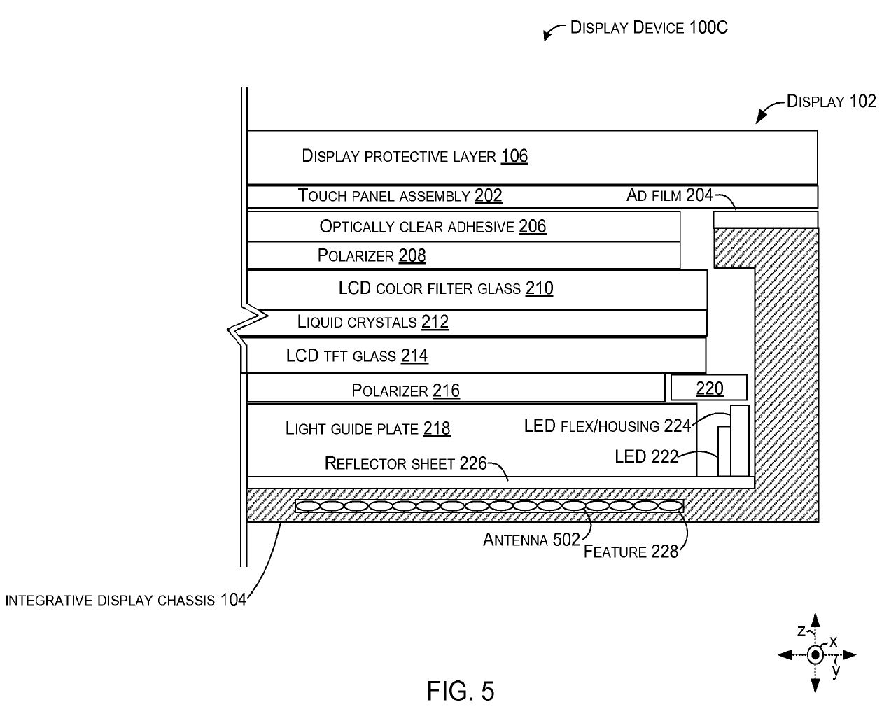

FIG. 5 shows another example display device 100C. In this case, the integrative display chassis 104 extends both vertically (e.g., in the z reference direction) as well as horizontally (e.g., in the y and x reference directions). In this example, the integrative display chassis 104 supports the reflective sheet 226 across the entire width of the reflective sheet. As such, a thinner reflective sheet can be utilized than with unsupported configurations (as in traditional display device 300 of FIG. 3). Also, in this case, the integrative display chassis 104 defines a feature 228 in which an antenna 502 is positioned. Accordingly, in this configuration, the integrative display chassis 104 can eliminate the need for dual chassis as employed in previous solutions as well as eliminating the need for a decorative housing. Thus, the integrative display chassis 104 can enable a functional display device while being the only chassis or housing of the display device. Thus, the integrative display chassis can reduce the number of components (e.g., chassis and housing) and eliminate their associated tolerances thereby increasing the active area of the display device. Additionally, the antenna positioned in the integrative display chassis 104 is protected from damage and avoids interference that is caused by traditional metal display chassis.

Further, the integrative display chassis 104 can provide display device integration to allow for a very thin display protective layer 106 with or without an integral/laminated touch panel assembly 202. The integrative display chassis 104 can provide support for the thin display protective layer where the display protective layer overhangs beyond the active area.

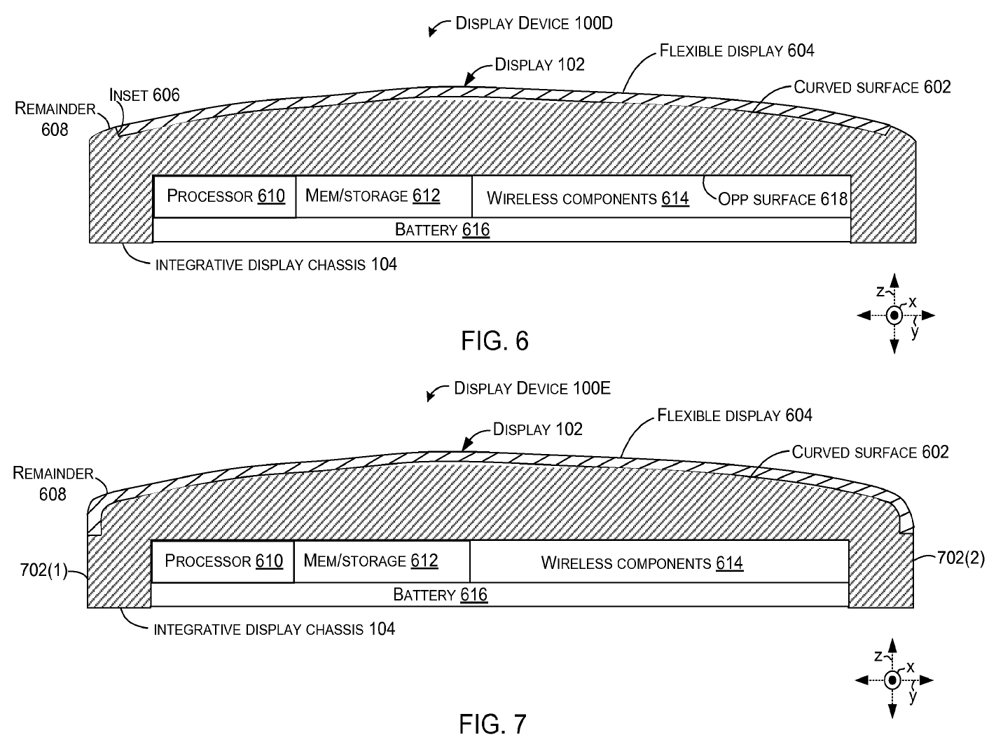

FIG. 6 shows another example display device 100D. In this example, integrative display chassis 104 includes a curved surface 602 (in this case a convex curved surface). The display 102 in the form of a flexible display 604, such as a flexible organic light emitting diode (OLED) display, is positioned over the curved surface 602 of the integrative display chassis 104 such that the curved surface 602 defines a shape of the flexible display. In some implementations, the curved surface 602 can include an inset 606 so that when the flexible display 604 is positioned in the inset the flexible display is flush with a remainder 608 of the curved surface 602. The flexible display 604 may include a display protective layer (see FIG. 1). The display protective layer may fit within the inset so that it is flush with the remainder 608 or the display protective layer may cover the remainder as well as the flexible display positioned in the inset.

The curved configuration of the integrative display chassis 104 can be useful in various device manifestations, such as a smart watch or other wearable smart device, or a smart phone, among others. In this example, the integrative display chassis can define a recess into which electronic components, such as processor 610, memory/storage 612, wireless components 614, and/or a battery 616, can be positioned and protected. In this example, the recess is formed in an opposite side or surface 618 of the integrative display chassis 104 from the curved surface 602. Further, the integrative display chassis can also function as a smart watch ‘case’ (e.g. housing) thereby eliminating the need for a dedicated case and associated tolerances (e.g., between the integrative display chassis and the case).

FIG. 7 shows another example display device 100E. In this example, curved surface 602 of integrative display chassis 104 extends onto sidewalls 702(1) and 702(2) of the integrative display device. The flexible display follows the curved surface and as such is visible from the z reference direction as well as the y reference direction.

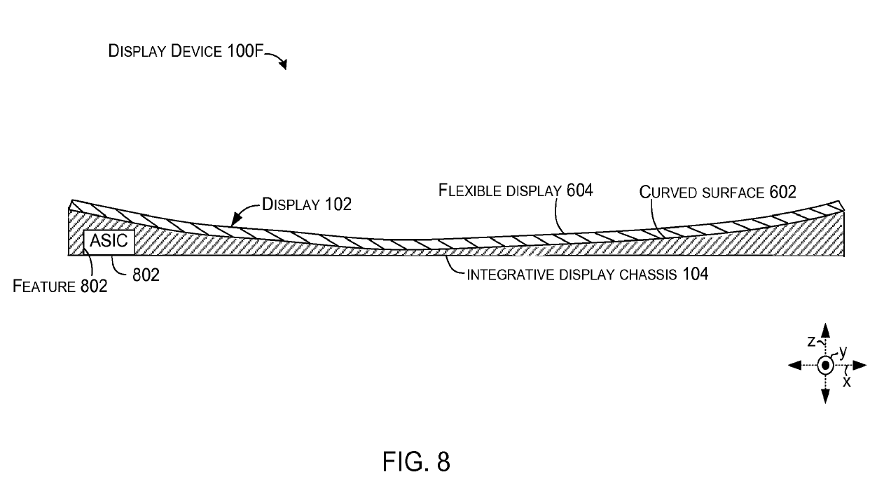

FIG. 8 shows another example display device 100F. In this example, integrative display chassis 104 includes a (concave) curved surface 602. The display 102 in the form of a flexible display 604, such as a flexible OLED display, is positioned over the curved surface 602 of the integrative display chassis 104 such that the curved surface 602 defines a shape of the flexible display 604. The curved configuration of the integrative display chassis 104 can be useful in various device manifestations, such as a curved television (TV). In this example, the integrative display chassis can define a feature 228 into which an ASIC 802 or other components can be positioned to drive the flexible display. This configuration can simplify the display device 100F such that the display device is manifest as two large elements: integrative display chassis 104 and the flexible display 604 with additional components positioned within features 802 of the integrative display chassis 104.

### ADDITIONAL EXAMPLES

Various device examples are described above. Additional examples are described below. One example is manifest as a display device that includes an integrative display chassis defining a major planar surface and having a feature formed relative to the major planar surface. The display device also includes a display positioned relative to the integrative display chassis and extending along the major planar surface defined by the integrative display chassis. The display device further includes an electronic component positioned in the feature and oriented relative to the major planar surface by the feature.

Another example can include any combination of the above and/or below examples where the feature is formed through the major planar surface.

Another example can include any combination of the above and/or below examples where the feature orients the electronic component orthogonally to the major planar surface.

Another example can include any combination of the above and/or below examples where the electronic component is a sensor.

Another example can include any combination of the above and/or below examples where the sensor is a visible light camera, a depth camera, or a proximity sensor.

Another example can include any combination of the above and/or below examples where the feature is formed as part of forming the integrative display chassis or wherein the feature is added to the integrative display chassis.

Another example can include any combination of the above and/or below examples where the display comprises an LCD color filter glass, liquid crystals, and an LCD thin film transistor glass, or where the display comprises an OLED.

Another example can include any combination of the above and/or below examples where the display is positioned in the integrative display chassis.

Another example can include any combination of the above and/or below examples where the display is flexible.

Another example is manifest as a display device that includes an integrative display chassis that entails a curved surface, as well as a flexible display positioned over a first side of the curved surface of the integrative display chassis. The display device further includes electronic components configured to drive the flexible display, the electronic components positioned proximate to an opposite side of the integrative display chassis from the curved surface.

Another example can include any combination of the above and/or below examples where the electronic components are secured to the opposite side.

Another example can include any combination of the above and/or below examples where the electronic components are positioned in features formed in the integrative display chassis.

Another example can include any combination of the above and/or below examples where the display device comprises a television, a smart watch, a wearable smart device, a tablet, or a smart phone.

Another example can include any combination of the above and/or below examples where the flexible display is secured to the first side of the curved surface of the integrative display chassis.

Another example can include any combination of the above and/or below examples where the display device further comprises a decorative housing positioned around at least a portion of the integrative display chassis over which the flexible display is not positioned or where the integrative display chassis is also configured to function as the decorative housing that is visible to a user of the display device.

Another example is manifest as a display device that includes an integrative display chassis and multiple display components positioned in the integrative display chassis. The display device also includes a display protective layer positioned on the integrative display chassis in light transmitting relation to the multiple display components. The integrative display chassis structurally supports the display components and the display protective layer and functions as a decorative housing of the display device.

Another example can include any combination of the above and/or below examples where the integrative display chassis is the only chassis in the display device.

Another example can include any combination of the above and/or below examples where the integrative display chassis defines a feature having an electronic component positioned therein.

Another example can include any combination of the above and/or below examples where the electronic component is a camera and where the feature orients the camera orthogonal to the display protective layer.

Another example can include any combination of the above and/or below examples where the electronic component is an antenna and the integrative display chassis electrically insulates the antenna from a remainder of the display device.

### CONCLUSION

Although techniques, methods, devices, systems, etc., pertaining to display devices employing integrative display chassis are described in language specific to structural features and/or methodological acts, it is to be understood that the subject matter defined in the appended claims is not necessarily limited to the specific features or acts described. Rather, the specific features and acts are disclosed as exemplary forms of implementing the claimed methods, devices, systems, etc.

1-15. (canceled)

16. A display device, comprising:
an integrative display chassis;
multiple display components positioned in the integrative display chassis; and,
a display protective layer positioned on the integrative display chassis in light transmitting relation to the multiple display components, wherein the integrative display chassis structurally supports the display components and the display protective layer and functions as a decorative housing of the display device.

17. The display device of claim 16, wherein the integrative display chassis is the only chassis in the display device.

18. The display device of claim 16, wherein the integrative display chassis defines a feature having an electronic component positioned therein.

19. The display device of claim 18, wherein the electronic component is oriented orthogonal relative to a display of the display device by the feature.

20. The display device of claim 18, wherein the electronic component is a USB port.

21. The display device of claim 16, wherein the integrative display chassis defines an upper surface, and the display protective layer is positioned on the upper surface.

22. The display device of claim 21, wherein at least some of the multiple display components are positioned below the upper surface.

23. The display device of claim 22, wherein the at least some of the multiple display components are assembled from a bottom of the display device up into the integrative display chassis.

24. The display device of claim 22, wherein the upper surface extends partially between the display protective layer and the at least some of the multiple display components.

25. The display device of claim 24, wherein the at least some of the multiple display components comprise an LCD color filter glass, liquid crystals, and an LCD thin film transistor glass.

26. A display device, comprising:
an integrative display chassis;
multiple display components positioned in the integrative display chassis; and,
a display protective layer positioned above the integrative display chassis in light transmitting relation to the multiple display components, the integrative display chassis extending partially between the display protective layer and at least some of the multiple display components.

27. The display device of claim 26, wherein the integrative display chassis defines a feature having an electronic component positioned therein.

28. The display device of claim 27, wherein the electronic component is a USB port or a sensor.

29. The display device of claim 28, wherein the sensor is a visible light camera, a depth camera, or a proximity sensor.

30. The display device of claim 26, further comprising a touch panel assembly.

31. The display device of claim 30, wherein the touch panel assembly is positioned above the integrative display chassis.

32. A display device, comprising:
an integrative display chassis defining a major planar surface and having a feature formed relative to the major planar surface;
a display positioned relative to the integrative display chassis and extending along the major planar surface defined by the integrative display chassis; and,
an electronic component positioned in the feature and oriented orthogonal relative to the major planar surface by the feature.

33. The display device of claim 32, wherein the major planar surface is positioned at least partially between multiple components of the display positioned below the major planar surface and a display protective layer positioned above the major planar surface.

34. The display device of claim 33, wherein the multiple components of the display positioned below the major planar surface comprise an LCD color filter glass, liquid crystals, and an LCD thin film transistor glass.

35. The display device of claim 32, wherein the integrative display chassis functions as a housing of the display device.
